(19) United States
(12) Patent Application Publication
(10) Pub. No.: US 2023/0093980 A1
(43) Pub. Date: Mar. 30, 2023

(54) Electricity Distribution System for a Domestic Installation, Method for Managing such an Electricity Distribution System

(71) Applicant: Schneider Electric Industries SAS, Rueil Malmaison (FR)

(72) Inventors: Bernard Lebeau, Les Adrets (FR); Etienne Du Port De Poncharra, Crets en Belledonne (FR); Emmanuel Bur, La Buisse (FR); Brice Fassi, Grenoble (FR)

(73) Assignee: Schneider Electric Industries SAS, Rueil Malmaison (FR)

(21) Appl. No.: 17/947,221

(22) Filed: Sep. 19, 2022

(30) Foreign Application Priority Data
Sep. 24, 2021 (FR) 2110100

(51) Int. Cl. H02J 3/00; H02J 3/38; H02J 3/04; G01R 19/00; B60L 53/62

(52) U.S. Cl. CPC H02J 3/007; B60L 53/62; G01R 19/0092; H02J 3/04; H02J 3/381; H02J 2300/24

(57) ABSTRACT

An electrical distribution system includes a distributor designed to distribute an electric current in an electrical installation, the distributor being configured to be connected to a distribution grid, to at least one secondary electrical power supply source and to a plurality of the electrical loads . An electronic control device is configured to manage power supply parameters of at least some of the electrical loads to reduce the electric current consumed and/or to manage operating parameters of at least some of the secondary electrical power supply sources in order to reduce the electric current delivered by these sources, so as to comply with a current threshold dictated by a protection element and/or by the distributor .

### TECHNICAL FIELD

The invention relates to an electricity distribution system for a domestic installation. The invention also relates to a method for managing such an electricity distribution system.

### BACKGROUND

Today, it is common for domestic electricity distribution installations to be supplied with power by multiple electrical sources, for example by a public distribution grid and by a local power supply source, such as one or more photovoltaic generators (PV).

Often, local power supply sources are connected to existing distribution installations. This is the case, for example, when photovoltaic generators are put into a residence already provided with a distribution installation.

For reasons of cost and ease of installation, these local power supply sources are frequently connected upstream of the distribution installation, alongside the incomer from the public distribution grid, and downstream of the main circuit breaker 11 (FIG. 1).

In this case, the main circuit breaker 11 is incapable of protecting the local installation if the total electric current (I_total) equal to the sum of the current coming from the grid (I_grid) and the current coming from the local source (I_PV) were to be above a safety threshold I_threshold (for example 63 amps) when the two sources generate electricity that is consumed by the loads of the domestic installation, since the main circuit breaker 11 is not situated on the same arm of the installation as the local power supply source.

Moreover, in many cases, domestic installations are generally not intended to supply power to high-power loads for long periods, which increases the risk of overcurrent.

FIG. 1 shows an example of such a configuration, wherein a domestic electricity distribution installation 10 is configured to be supplied with power by a public distribution grid 12 and by photovoltaic generators 13, these two power supply sources being connected by a common connection 14 to an input of one and the same distributor 16. The output of the distributor 16 is connected to conductors 18 that supply power to a plurality of domestic electrical loads 20.

With such a configuration, the main circuit breaker 11 cannot trip when the total current (I_total) is above the safety threshold I_threshold (maximum current admissible by the switchboard) while the current coming from the grid (I_grid) remains below the tripping threshold of the main circuit breaker 11.

Such a situation may create serious safety problems, such as a risk of fire, and must therefore be avoided.

There is therefore a need for a domestic electrical installation that allows one or more secondary power supply sources to be easily connected alongside the incomer from the power supply grid without compromising the safety of the installation.

### SUMMARY

To that end, one aspect of the invention relates to an electrical distribution system for distributing electric currents between an electrical distribution grid and a domestic distribution installation, wherein the system comprises:
a distributor designed to distribute an electric current in the installation, the distributor being configured to have its upstream side connected to an electrical distribution grid and to at least one secondary electrical power supply source, the distributor being configured to have its downstream side connected to a plurality of the electrical loads,
an electronic control device connected to measuring devices associated with the sources and with the loads, these measuring devices allowing determination of the electric current flowing in the installation and in particular of the electric current carried in the electrical distribution grid,
the electronic control device being configured to take the measured current as a basis for managing power supply parameters of at least some of the electrical loads to reduce the electric current consumed by these electrical loads and/or for managing operating parameters of at least some of the secondary electrical power supply sources in order to reduce the electric current delivered by these electrical sources, so as to comply with a first current threshold dictated by a protection element between the electrical installation and the electrical distribution grid and/or a second current threshold corresponding to a current limit dictated by the distributor so as to prevent the current delivered by the electrical sources through the distributor from exceeding the current limit dictated by the distributor.

According to advantageous but not obligatory aspects, such a system may incorporate one or more of the following features, taken in isolation or according to any technically admissible combination:
the electronic control device is configured to manage the power supply parameters of at least some of the electrical loads to reduce the electric current consumed by these loads and/or to manage operating parameters of at least some of the secondary electrical power supply sources in order to reduce the electric current delivered by these electrical sources, so as to comply with the first current threshold and the second current threshold;
managing power supply parameters of at least some of the electrical loads comprises steps consisting in at least automatically disconnecting or reconnecting said electrical load/s, or modulating the electrical consumption by said electrical load/s;
said plurality of electrical loads comprises one or more of the following elements: an electric vehicle or a charging station for an electric vehicle, a water heater, a heat pump, or air-conditioner, or a pump;
the system comprises one or more electrical switching devices for selectively disconnecting or reconnecting one or more of said electrical loads, the switching device/s being controlled by the electronic control device;
at least one of said electrical loads comprises an integrated regulating device connected to the electronic control device, the integrated regulating device being configured to control the electrical consumption by said electrical load on the basis of information sent by the electronic control device;
said electrical load is a charging station for an electric vehicle;
each of said electrical loads is connected to the distributor by way of an electrical conductor;
at least one secondary electrical power supply source comprises photovoltaic generators;
the system comprises at least one electricity storage system that may be a source or a load;
an alternative secondary electrical power supply source comprises a generator set;
the distributor comprises copper electrical conductors;
the protection element comprises an electrical protection unit such as a circuit breaker or a fuse or a power-limited energy meter;
the distributor is also configured to have its downstream side connected to additional electrical loads, such as domestic electrical loads, for example lighting.

According to another aspect, the invention relates to a method for managing an electrical distribution system for distributing electric currents between an electrical distribution grid and an electrical switchboard in a domestic installation, wherein the system comprises a distributor and an electronic control device, the distributor being designed to distribute an electric current in the installation, the distributor being configured to have its upstream side connected to an electrical distribution grid and to at least one secondary electrical power supply source, the distributor being configured to have its downstream side connected to a plurality of electrical loads, wherein the electronic control device is configured to:
determine, by means of measuring devices associated with the sources and with the loads, the electric currents flowing in the installation, and in particular the electric current carried in the electrical distribution grid,
take the measured current as a basis for managing power supply parameters of at least some of the electrical loads, to reduce the electric current consumed by these electrical loads, and/or for managing operating parameters of at least some of the secondary electrical power supply sources in order to reduce the electric current delivered by these electrical sources, so as to comply with a first current threshold dictated by a protection element between the electrical installation and the electrical distribution grid and/or a second current threshold corresponding to a current limit dictated by the distributor so as to prevent the current delivered by the electrical sources through the distributor from exceeding the current limit dictated by the distributor.

### BRIEF DESCRIPTION OF THE DRAWINGS

The invention will be better understood and other advantages thereof will emerge more clearly in the light of the description that follows for an embodiment of a system provided solely by way of example, which description is given with reference to the appended drawings, in which:

FIG. 1 schematically shows an electrical installation based on the prior art;

FIG. 2 schematically shows an electrical installation in accordance with the invention;

FIG. 3 schematically shows a method for operating the electrical installation in FIG. 2;

FIG. 4 schematically shows some of the steps of the method of operation in FIG. 3;

FIG. 5 schematically shows some of the steps of the method of operation in FIG. 3;

FIG. 6 schematically shows some of the steps of the method of operation in FIG. 3.

### DETAILED DESCRIPTION

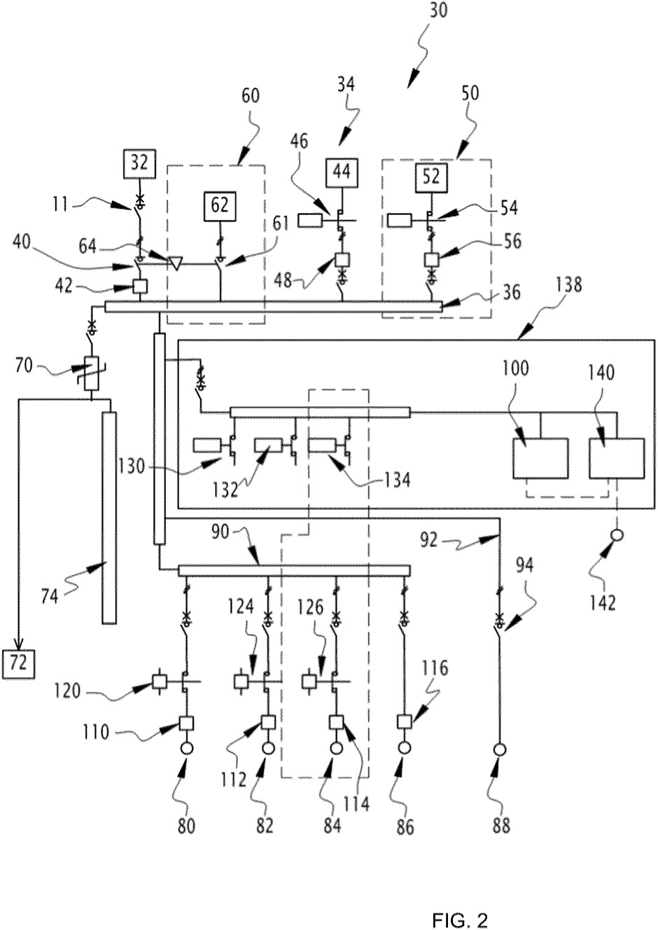

FIG. 2 shows an embodiment, in accordance with the invention, of an electricity distribution system 30 for a domestic installation.

In many embodiments, at least some of the constituents of the system 30 are accommodated in an electrical switchboard, the latter being able to be at least partly installed in an electrical switchboard (for example a wall switchboard) or in an electrical enclosure.

The system is configured to be supplied with power by an electrical distribution grid 32 (mains) and by at least one secondary power supply source 34.

The system 30 here comprises a connection point comprising connection terminals intended to be connected to the grid 32. According to the embodiments, this may be a single-phase or polyphase (for example three-phase) connection point with or without a neutral line.

Between the system 30 and the grid 32 there is a protection element, which bears the numerical reference 11 here. This protection element 11 may comprise an electrical protection unit, such as a circuit breaker or a fuse or a power-limited energy meter, for example.

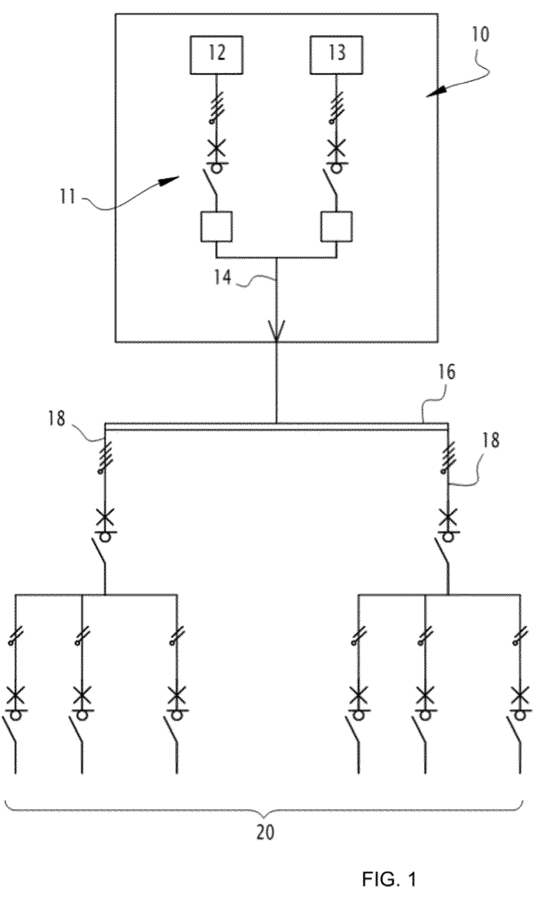

In the example shown, the protection element 11 comprises a circuit breaker, referred to as the main circuit breaker, which corresponds to the main circuit breaker 11 described with reference to FIG. 1.

It is therefore understood that the constraint that aims to monitor or indeed limit the current flowing through this protection element 11 so as not to exceed the tripping threshold I_threshold may be generalized in case the protection element 11 is something other than a circuit breaker. It is therefore a matter, for example, of not exceeding a current that could lead to damage to an electrical conductor of the protection element 11, for example.

The system 30 also comprises a distributor 36 designed to distribute an electric current in the installation.

The distributor 36 allows multiple electrical loads to be connected to one and the same current supply, for each electrical phase conductor (and also for the neutral line, if applicable, according to the type of installation).

In this example, the electrical installation is a single-phase installation with a neutral line, other examples nevertheless being possible as a variant. By way of example, the system 30 could be adapted to operate in a three-phase installation.

In many embodiments, the distributor 36 comprises a plurality of connecting strips, or connecting rails, preferably made from copper or any appropriate electrically conductive material, each connecting strip being associated with one electrical phase (or with a neutral line), for example.

For example, the distributor 36 is designed to withstand and distribute an electric current of intensity greater than or equal to 96 amps, for example greater than or equal to 120 amps.

The distributor 36 is configured to have its upstream side connected to the electrical distribution grid 32 and to each of the secondary power supply sources.

Preferably, a disconnector switch 40 situated downstream of the protection element 11 is connected between the grid 32 and the distributor 36. For example, the disconnector switch is a modular switch (miniature switch). For example, the current rating of the disconnector switch 40 is designed to carry the current of the protection element 11, for example 63 amps.

The main circuit breaker is therefore connected upstream of the distributor 36.

The current threshold used to regulate this main circuit breaker is generally dependent on the subscription taken out with the manager of the grid 32.

Connected downstream of the disconnector switch 40 here is a measuring device 42, for example configured to measure an electric current and/or an electrical power passing through the corresponding electrical conductor/s. The role of this measuring device 42 will be explained in the text that follows.

In the example shown, the system 30 comprises multiple secondary electrical power supply sources, examples of which will be described below with reference to the configuration shown in FIG. 2. The number and nature of the secondary electrical power supply sources may differ according to the possible embodiments.

Preferably, at least one secondary electrical power supply source or generator comprises photovoltaic panels (PV). The system 30 may thus comprise one or more photovoltaic generators acting as a secondary electrical power supply source. It may also comprise a “dimmable” battery electricity storage system that may be a source or a load.

In the example shown, the first secondary electrical power supply source 34 comprises a first photovoltaic generator 44 made up of photovoltaic panels associated with an inverter connected to the distributor 36, for example, by way of electrical conductors, which are here provided with a protection relay 46 and a differential circuit breaker equipped with a measuring circuit 48. The protection relay 46 and/or the differential circuit breaker equipped with a measuring circuit 48 could be removed to outside the system 30 as a variant, however.

Still in the example shown, the second secondary electrical power supply source 50 comprises a second photovoltaic generator 52, similar to 44, connected to the distributor 36, for example, by way of electrical conductors, which are here provided with a protection relay 54 and a differential circuit breaker equipped with a measuring circuit 56, which are similar to those of the source 34.

In the example shown, the third source 60 is an auxiliary source of generator set 62 type. The system comprises a disconnector switch (not referenced) interlocked with the disconnector switch 40 and connected to the distributor 36.

In some embodiments, an electricity storage system, comprising for example a set of electric chemical batteries, could be used as an additional electrical power supply source.

This optional auxiliary source 60 comprises a safety interlock 64, or interlocking device, that allows the source 32 to be interlocked with the source 62 in order to permit only a single one of these two sources to be connected to the distributor 36. In other words, the device 64 allows selection of which of the sources 32 or 62 supplies power to the distributor 36, by preventing the two sources from being connected simultaneously.

In the example shown, the device 64 comprises a first switch, for example the aforementioned disconnector switch 40, which is placed between the connection point of the grid 32 and the distributor 36, and a second switch 61 placed between the generator set 62 and the distributor 36. For example, the second switch is kept in the open state while the first switch is in the closed state, and vice versa.

The device 64 may be of mechanical or electromechanical or electronic type, other embodiments nevertheless being possible.

As a variant, the source/s 50 and/or 60 could be omitted.

Optionally, the system 30 may comprise a lightning protection device. This lightning protection device is connected to the distributor 36, for example on the downstream side of the distributor 36. In the example shown, the lightning protection device comprises a varistor 70 connected between the distributor 36 and a point for connection to the earth 72 of the electrical installation, which point is connected to the terminal block for connection to the earth 74.

The distributor 36 is also configured to have its downstream side connected to a plurality of electrical loads.

The distributor 36 is thus capable of supplying electrical power to the electrical loads, by transferring at least part of the electric current generated by one or more of the electrical sources 32, 34, 50 and 60 connected upstream. These main loads are connected in parallel here.

In FIG. 2, the electrical loads correspond to the references 80, 82, 84, 86 and 88, it being understood that this example is nonlimiting and that there may be provision for a different number of electrical loads as a variant.

In many embodiments, among these electrical loads, a distinction may be drawn between two types of electrical loads: electrical loads referred to as critical (or main loads) 80, 82, 84 and 86 and domestic electrical loads 88 (or secondary loads).

For example, the main electrical loads 80, 82, 84 and 86 correspond to electrical loads that are likely to consume high electrical powers (compared to ordinary domestic electrical loads) and/or to consume electric currents of high electrical intensity, and/or to be continuously active for long periods (for example for more than 10 hours).

For example, the main electrical loads comprise one or more of the following elements: an electric vehicle or a charging station for an electric vehicle, a water heater, a heat pump (or air-conditioner, or more generally a domestic heating installation), an air-conditioner or a swimming pool heating system.

In the example shown, these loads correspond to the references 80, 82, 84 and 86.

By comparison, domestic electrical loads, which are represented in FIG. 2 by the numerical reference 88, consume a lower electrical power and their operation is generally intermittent.

For example, the domestic electrical loads 88 are lighting elements, or domestic appliances plugged into domestic electrical sockets, such as household appliances, multimedia appliances, computer equipment, lights, these examples being nonlimiting.

In practice, each of said electrical loads 80, 82, 84, 86 and 88 is connected to the distributor 36 by way of an electrical conductor (or multiple phase and/or neutral conductors, depending on the nature of the electrical installation).

Preferably, the electrical conductors are designed on the basis of the maximum admissible current per corresponding electrical load, for example by being designed exactly so as not to have to overdimension the electrical conductors. This allows the amount of material used to be saved and therefore the cost of the installation to be reduced.

For example, the main electrical loads 80, 82, 84 and 86 may be connected to the distributor 36 by way of conductors associated with distribution combs 90 (or a secondary distributor), as is the case with what are shown in FIG. 2, or they may be connected directly to the distributor 36 by an electrical conductor.

The secondary electrical loads 88, the connection terminals of which are generally gathered together in a secondary panel, may, for their part, be connected directly to the distributor 36 by an electrical conductor 92 protected by a circuit breaker 94, the rating of which is designed so as not to exceed the maximum admissible current of the secondary panel, for example 63 A.

In practice, the electrical conductors are connected to connecting terminals allowing these electrical loads to be connected. The secondary electrical loads 88 may be connected by multiple secondary cables or conductors distributed from the secondary panel.

In the example shown, the load 80 is an electrical water heater comprising at least one first heating means such as a heat pump or an electrical resistor. The load 82 is a heat pump (or air-conditioner). The load 84 is another controlled load (for example a swimming pool pump). The load 86 is a charging station for an electric vehicle. This example is nonlimiting, other embodiments being possible as a variant. For example, the electrical water heater could comprise just a single heating means (for example the resistor).

The system 30 also comprises an electronic control device 100 configured to automatically manage the distribution of the electric current between the electrical loads.

In many embodiments, the electronic control device 100 is implemented by one or more electronic circuits, for example by a programmable logic controller (PLC).

For example, the electronic control device 100 comprises a processor, such as a programmable microcontroller or a microprocessor. The processor is coupled to a computer memory, or to any computer-readable data recording medium, that comprises executable instructions and/or a software code provided for administering a method for managing the system 30 that will be described below when these instructions are executed by the processor.

The use of the term “processor” does not prevent, as a variant, at least some of the functions of the electronic control device 100 from being performed by other electronic components, such as a processor for processing the signal (DSP), or a reprogrammable logic component (FPGA), or a specialized integrated circuit (ASIC), or any equivalent element, or any combination of these elements.

In particular, the electronic control device 100 is configured to manage parameters for supplying power to at least some of the electrical loads and/or to automatically disconnect or reconnect one or more of the electrical loads on the basis of the measured current, when the current flowing through the distributor 36 exceeds a current threshold, such as a protection threshold.

For example, the electronic control device 100 is connected to sensors allowing determination of the electric current flowing in the installation.

Preferably, the system 30 comprises devices for measuring electrical variables, such as the electric current and/or the voltage and/or the electrical power, associated with the electrical loads (at least for the main loads) and with the electrical sources. These measuring devices may comprise current sensors and/or voltage sensors or any other suitable measuring unit. For example, in FIG. 2, measuring circuits 110, 112, 114 and 116 measure the currents flowing to the main loads 80, 82, 84 and 86. The measuring devices 42, 48 and 56 associated with the electrical sources may also be used for this purpose.

This allows determination of the electric current flowing in the installation and in particular of the electric current flowing through the distributor 36. Ideally, a measuring device 42 is associated with the source 32, with each secondary source and with each main electrical load.

The electronic control device 100 is also connected to electrical switching devices, such as remotely controllable switches, in order to selectively disconnect or reconnect one or more of the electrical loads, or indeed all of the electrical loads. The electrical switching devices may be relays, or contactors, or semiconductor-based power switches, or any other equivalent unit.

In the example in FIG. 2, each main load 80, 82 and 84 has an associated electrical switching device (numbered 120, 124 and 126, respectively) that is selectively and reversibly switchable between an open state and a closed state in order to disconnect the corresponding load of the distributor or in order to connect this load to the distributor 36, respectively.

The electronic control device 100, here placed in a control assembly 138, is configured to control the electrical switching devices 120, 124 and 126 so as to manage power supply parameters of at least some of the electrical loads.

In particular, the device 100 is configured to take the measured current as a basis for managing power supply parameters of at least some of the electrical loads, to reduce the electric current consumed by these loads, and/or for managing operating parameters of at least some of these electrical loads in order to reduce the electric current consumed by these electrical loads, so as to comply with the current threshold dictated by a main circuit breaker connected between the electrical installation and the electrical distribution grid.

The device 100 is also configured to manage the power supply parameters of at least some of the electrical loads so as to prevent the current delivered by the electrical sources through the distributor from exceeding the current limit dictated by the distributor.

For example, it may be a matter of automatically disconnecting or reconnecting one or more of the electrical loads on the basis of the current measured for a load-shedding action, in order to prevent the consumed current flowing through the distributor 36 from exceeding the protection threshold, and/or also to adjust the electrical power consumed by the electrical loads on the basis of the electrical power subscribed for with the manager of the grid 32 (which governs the threshold of the main circuit breaker 11) and the electrical power that the secondary sources 34, 50 and 60 are capable of providing.

In the example shown, the electronic control device 100 is associated with control lines that are associated with the electrical switching devices 120, 124 and 126, respectively. These lines are connected to a secondary distributor 90 supplied with power from the distributor 36 and are each provided with a controllable switch, such as a relay or a semiconductor-based power switch, which are denoted 130, 132 and 134, so as to trigger the switching of the corresponding electrical switching device by selectively supplying power to the control line.

When the switch 120, 124 or 126 is in the open state, the corresponding electrical load is disconnected from the system 30 and cannot be supplied with electric power by a current flowing from the distributor 36.

Depending on the nature of the electrical installation, the electronic control device 100 may, also or alternatively, be connected to control means, such as a regulating device integrated in some of the electrical loads, in order to remotely control these electrical loads (for example in order to reduce their consumption or to temporarily stop them).

This is particularly the case of loads such as a heat pump (or air-conditioner), or a charging unit for an electric vehicle, such as the load 86 in the example shown in FIG. 2, which generally comprise such regulating devices (usually implemented by electronic controllers), which are able to communicate with the electronic control device 100.

For example, the communication between the electronic control device 100 and the regulating device of the charging terminal for an electric vehicle (terminal 142 in FIG. 2) is provided here by virtue of a link based on the Open Charge Point Protocol (OCPP). Other communication methods could be used as a variant.

In the example shown, the electronic control device 100 comprises a communication interface 140 such as a router or a gateway, which is in communication with a control device of one of the main loads (for example the charging station 86), or indeed with an external communication network (for example the Internet).

In other cases, the main loads may be controlled by supplying electric power (or by interrupting the supply of power) to a secondary connecting terminal connected to a control input of the electrical load.

Owing to the invention, the distribution system allows multiple power supply sources (and more particularly a photovoltaic source and a public grid) to be easily associated in order to supply power to a domestic installation comprising a plurality of electrical loads of different nature, while preventing the association of multiple electrical sources from generating electric currents whose intensity would be dangerous for the installation and unstable if production of the photovoltaic panel were absent.

The device 100 in particular allows two aspects to be monitored and regulated: firstly, guaranteeing compliance with the contract taken out with the manager of the grid 32 (or, more generally, complying with the current threshold defined by the protection element 11) and, more generally, managing the self-consumption by the system, that is to say managing the electrical power provided by the secondary sources.

Secondly, it is a matter of protecting the distributor 36 and in particular of making sure that the sum of the currents coming from the various sources, in particular when at least some of the secondary sources are active, does not exceed the limits permitted by the distributor 36 and by the installation in general.

As a variant, the device 100 could be configured just to monitor and regulate one of these two aspects: complying with the current threshold defined by the protection element 11 and managing the self-consumption by the system, or protecting the distributor 36.

It is therefore understood that the embodiments allowing each of these aspects to be managed may be administered independently of the embodiments allowing the other of these aspects to be managed, and that, in many embodiments, the device 100 is capable of managing these two aspects.

Regulation of the current is performed automatically without needing to add circuit breakers for each secondary electrical source. Moreover, as the distribution of the electric currents in the installation is controlled (by shedding one or more loads when the current flowing in the corresponding arms becomes too high), this allows the conductors and the distributor 36 to be designed to match needs as closely as possible. Excessive overdimensioning of the electrical conductors of the installation is thus avoided, such overdimensioning generally having the effect of giving rise to higher production costs and greater weight (in the case of copper conductors, for example). This dual monitoring also yields an advantage in terms of comfort for users by preventing inadvertent tripping of the main circuit breaker.

Generally, the electronic control device 100 is configured to manage the consumption by the loads to reduce the current delivered by the electrical sources (such as the current coming from the grid 32 and routed by the main circuit breaker) through the distributor 36.

The device 100 is configured to monitor this current and to control the main electrical loads and/or the secondary sources in order to comply with the safety threshold (I_threshold) of the main circuit breaker so as to prevent any inadvertent disconnection, which would have a negative impact on the comfort of users of the electrical installation.

At the same time, the device 100 is configured to monitor this current and to control the main electrical loads and/or the secondary sources in order to comply with the limit dictated by the distributor 36 (for example an electric current of intensity 96 A or 120 A). The device 100 may also be configured to monitor an injection of current towards the grid (related to lower consumption by the loads than the total production by the additional sources) in order to force consumption by the electrical loads.

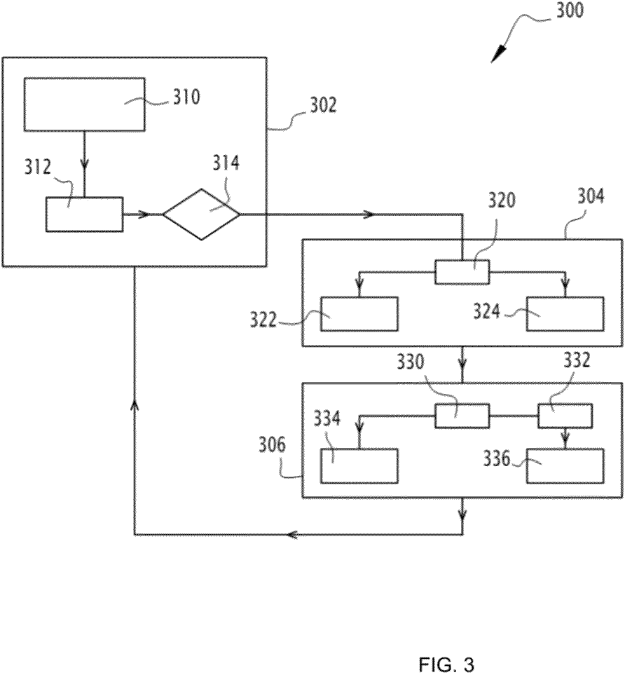

FIG. 3 shows an example of a method for managing the system 30 or 200 that is carried out by the electronic control device 80.

We note that, as a variant, the steps could be performed in a different order. Some steps could be omitted. The example described does not prevent, in other embodiments, other steps from being carried out jointly and/or sequentially with/to the steps described.

Generally, as illustrated by the diagram 300, the electronic control device is configured to:
determine, by means of sensors, the electric current flowing in the installation (block 302),
manage power supply parameters of at least some of the electrical loads and/or automatically disconnect or reconnect one or more of the electrical loads on the basis of the measured current. This corresponds to steps of shedding (block 304) and restoring (block 306) the electrical loads in question.

Generally, as explained above, the method has a dual finality.

Firstly, it involves monitoring and managing the consumption by the electrical loads on the basis of the contract taken out with the manager of the grid 32, in particular so that the current provided by the grid does not exceed the threshold fixed by the subscription (for example 40 A or 60 A), because this could lead to tripping of the main circuit breaker.

Secondly, it involves preventing the current flowing through the distributor from exceeding a current threshold, in particular in order to prevent the currents provided by the grid 32 and by the intermittent sources from rising above the protection threshold defined on the basis of the current admissible by the distributor 36.

Thus, the steps of this method may be carried out multiple times: a first time in order to detect whether the current provided by the grid 32 exceeds the threshold fixed by the subscription (I_Grid compared to I_threshold of the element 11) and a second time in order to detect whether the current exceeds the protection threshold (I_grid + I_sum_of_the_sources) above I_threshold of the distributor 36. These sequences of steps must themselves be repeated over the course of time.

The text that follows will describe the steps with reference to the second application (that the current provided by the grid does not exceed the current threshold admissible by the distributor 36), but it is understood that in practice these steps will also be used for the first application.

In the example shown, in step 302, the device 100 measures electrical variables by means of the sensors and the measuring devices 42, 48, 56, 110, 112, 114 and 116 and determines (directly and/or by way of calculations) values of electric currents and/or values of electric power at one or more sites of the distribution installation.

Next, the device 100 compares the measured variables 310 with reference variables, which may be protection thresholds that, when exceeded, indicate the occurrence of an overcurrent.

In some examples, the comparison may be performed by calculating a ratio between electrical variables (a measured electrical variable and a predefined limit) and comparing this ratio with a predefined numerical value.

For example, an indicator called “current ratio” is used, which is defined as being equal to the ratio of the current flowing at a point in the installation (in the distributor 36) divided by a current threshold, such as the protection threshold defined above (for example equal to 96 A or 120 A).

As a variant, one could use a power ratio defined as being equal to the electrical power delivered by the grid 32 divided by a predefined electrical power limit (these powers being able to be instantaneous powers, or powers averaged over an identical period).

For example, at least one of said ratios is calculated in step 312, and then, in step 314, the device 100 determines whether an overcurrent has been identified from the value of the calculated ratio/s.

If an overcurrent has been identified, then, in block 304, the device 100 carries out a load-shedding method in order to interrupt the operation of at least one of the main loads, to reduce the electrical consumption and thus reduce the current delivered by the electrical sources through the distributor 36 or the protection element 11 and/or adapt the consumption on the basis of the power available on the grid 32 (on the basis of the supply contract taken out, which limits the available power or current) and the power available on the secondary sources, in particular on the intermittent sources such as the photovoltaic generators 44 and 52.

For example, in a step 320, the device 100 automatically determines which loads may be shed. For example, a list of electrical loads managed by the system, and their features, is recorded in memory beforehand.

This determination is for example carried out in accordance with a predefined control law, for example by means of known load-shedding management algorithms.

In practice, depending on the nature of the electrical loads present, it is possible to reduce their consumption gradually without totally interrupting the electrical load (dimmable loads) or even completely interrupting the load (and therefore stopping their consumption) by disconnecting them or stopping them.

An example of regulable load, the consumption of which may be varied gradually, is heating or air-conditioning equipment, the setpoint temperature of which may be modified to heat less (or to cool less). It may also be a charging terminal for electric vehicles that has a decreased charging output.

When applicable, this regulation is performed by means of the regulating device integrated in the corresponding electrical load.

Thus, following step 320, the device 100 automatically sends orders to reduce the consumption of one or more loads (step 322) and/or orders to disconnect a load (step 324).

Depending on the nature of the load and its connection to the system 30, the disconnection order is sent directly to the load so that it interrupts itself, or to a switching device situated between the distributor 36 and a power supply input of the load, as will be explained in more detail by way of examples presented below.

Next, in step 306, the load/s are restored, for example once the fault condition has disappeared and/or when a predefined timeout has elapsed.

For example, in step 330, the device 100 automatically determines which of the previously targeted loads is or are able to be restored. This determination may be carried out on the basis of known features of said loads, in accordance with a predefined control law, just like the method in step 320.

Thus, following step 330, the device 100 automatically sends orders to gradually restore the consumption by one or more variable loads (step 334) and/or orders to reconnect a load (step 336) after a timeout (step 332).

Step 302 is then repeated.

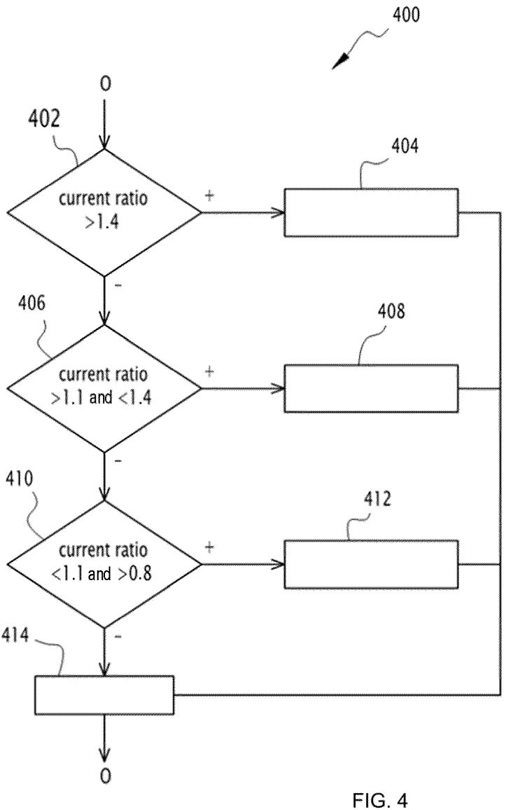

FIG. 4 shows an example of carrying out the steps of shedding one or more electrical loads of the system in a simplified manner in the method in FIG. 3.

The method 400, which provides details of an example of operation of the step carried out in the aforementioned block 302, starts after the ratios described above have been calculated.

In step 402, the current ratio (marked as such in FIG. 4) is compared with a first threshold (chosen here to be equal to 1.4, although other examples are possible). If the calculated ratio is above the first threshold, then the load/s in question are immediately interrupted (step 404 then step 304).

Otherwise, the current ratio is compared (step 406) with a second threshold (chosen here to be equal to 1.1, although other examples are possible). If the calculated ratio is above the second threshold, while being below the first threshold, then the load/s in question are interrupted after a first timeout, for example equal to 20 seconds (step 408 then step 304).

If neither of the two conditions is satisfied, then the current ratio (marked as such in FIG. 4) is compared with predefined thresholds (here equal to 0.8 and 1.1, other examples nevertheless being possible) in step 410. If the calculated ratio is between the first threshold and the second threshold, then the load/s in question are interrupted after a second timeout, for example equal to 300 seconds (step 412 then step 304).

The method ends in step 414.

As a variant, the values of the thresholds of the current ratios (first and second threshold values) could take different values. These threshold values are preferably chosen on the basis of the properties of the protection element 11 of the installation and the desired level of electrical protection, for example on the basis of the maximum current rating supported by the distributor and/or by the electrical conductors used to distribute the current between the sources and the electrical loads. The same goes for the timeout values. In particular, first and second threshold values may be defined for the various iterations of the method (the aforementioned first and second finalities).

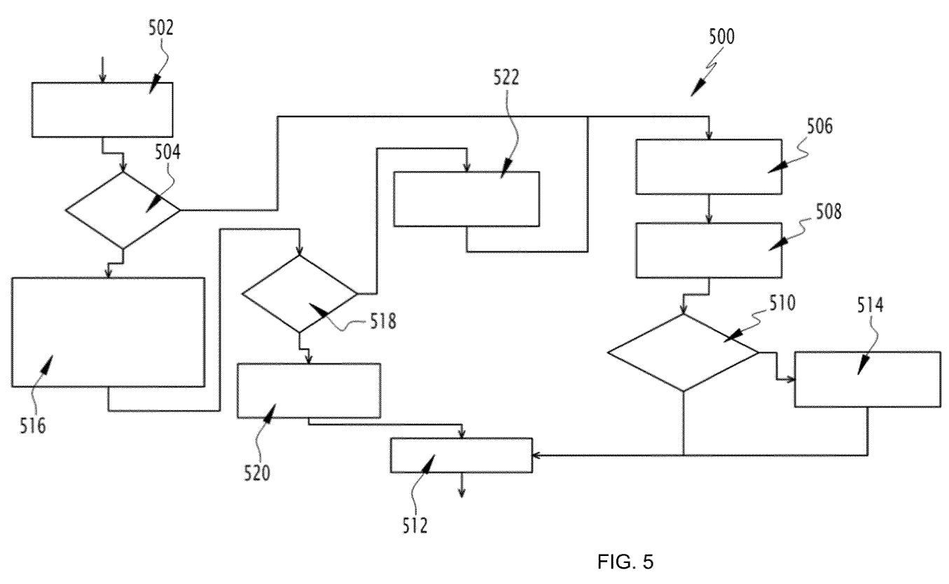

FIG. 5 provides details of an example of operation (method 500) of the step carried out in the aforementioned block 304 in order to control the shedding of one or more electrical loads.

In this example, the load-shedding acts on some loads as a matter of priority over others (in particular easily modulable or disconnectable loads) on the basis of their nature. For example, the aim is first of all to disconnect or limit the load of the electric vehicle, and then that of a load such as the water heater or the air-conditioning. The choice of the water heater is justified here by the fact that temporarily stopping the water heater will not lessen the comfort of the users since there is a reserve of hot water that the user is able to draw even when the heating means of the water heater are temporarily deactivated.

The method starts in step 502, once a load-shedding order has been sent and, if necessary, the period corresponding to the timeout has elapsed.

In step 504, the electronic control device 100 checks whether an electric vehicle is connected to the charging terminal and checks whether the batteries of this vehicle are not full.

If no vehicle is connected or if the batteries are full, then, in a step 506, the water heater is temporarily interrupted. For example, the device 100 disconnects the electrical load 80, here by means of the switching device 120, then triggers a timer, during which the supply of power to the load 80 will remain interrupted.

A new current ratio is computed in step 508, then a comparison with the limit threshold is carried out in a step 510.

For example, if the complete method is carried out in order to determine whether the current consumed is within the limits of the parameters of the subscription taken out with the manager of the grid 32, then step 510 may comprise comparison of the ratio with a first value chosen specifically on the basis of the threshold defined in the contract.

If the comparison shows that the new ratio is below the limit threshold, then the method 500 ends in step 512. A message may be sent in order to indicate that load-shedding is active.

If the comparison shows that the new ratio is above the limit threshold in spite of everything, then the electronic control device 100 disconnects another electrical load.

For example, in a step 514, the heat pump (or air-conditioner) (load 82) is disconnected, here by means of the switching device 124, and a timeout is imposed, during which this load will not be resupplied with power. The method may then end directly in step 512.

If, at the end of step 504, a vehicle has been identified as being connected to the charging terminal and the batteries of said vehicle are not full, indicating that the vehicle is potentially being charged, then, in a step 516, a new charging setpoint is calculated for the electric vehicle, for example in order to reduce the electrical power consumed.

In a step 518, the device 100 checks whether the charging setpoint of the charging station is negative, indicating that the current to be reduced is above the only demand of the electric vehicle. If this is the case, then a new charging setpoint is chosen to be equal to zero in a step 522 in order to deactivate the charging terminal, and the method moves to step 506, described above, in order to disconnect another load.

If the charging setpoint of the charging station is positive or zero, then the new charging setpoint calculated is assigned to the charging terminal, which will be transmitted to the electric vehicle in a step 520. The method then ends in step 512.

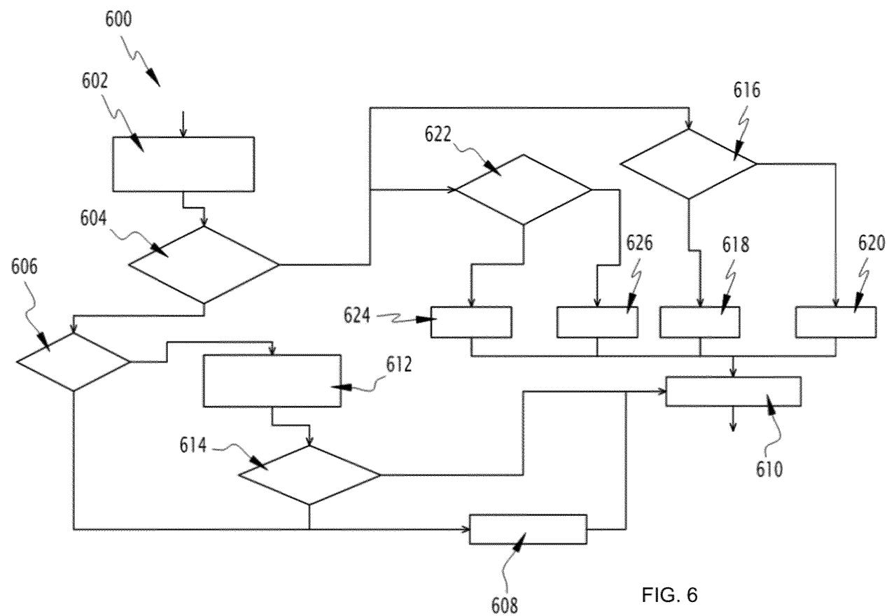

FIG. 6 provides details of an example (method 600) of operation of the step carried out in the aforementioned block 306 in order to reactivate one or more electrical loads once the load-shedding needs to end.

The method starts in step 602, once an order to end the load-shedding has been sent.

In step 604, the electronic control device 100 checks whether at least one or other of the water heater or the heat pump (or air-conditioner) has stopped, following the load-shedding.

If none of these loads is identified as being stopped, then, in a step 606, the device 100 checks whether an electric vehicle is connected to the charging terminal and checks whether the batteries of this vehicle are not full.

If no vehicle is connected or if the batteries are full, then, in a step 608, a message is sent (or a register is updated) in order to indicate that the load-shedding has ended. The method then ends in a step 610.

If, at the end of step 606, a vehicle has been identified as being connected to the charging terminal and the batteries of said vehicle are not full, indicating that the vehicle is potentially being charged, then, in a step 612, the device 100 calculates a new charging setpoint for the charging terminal, for example in order to increase the electrical power consumed by the electric vehicle.

In a step 614, the device 100 checks whether the new charging setpoint calculated is above the maximum setpoint. If this is the case, then the method moves to step 608 and ends in step 610.

If the new charging setpoint calculated is below the maximum setpoint, then the method moves directly to step 610.

Returning to step 604, if the device 100 identifies that at least one of the other loads, such as the water heater or the air-conditioner, is already stopped, then one or more checks are set up.

In a step 616, the device 100 checks whether the timeout imposed on the heat pump (or air-conditioner) (load 82) has come to an end. If this is the case, then, in a step 618, the load 82 is reconnected (for example by acting on the switching device 124) in order to resupply power to the heat pump (or air-conditioner). Otherwise, in a step 620, the load 82 remains disconnected. The method ends in step 610.

In parallel, in a step 622, the device 100 checks whether the timeout imposed on the water heater (load 80) has come to an end. If this is the case, then, in a step 624, the load 80 is reconnected (for example by means of the switching device 120) in order to resupply power to the water heater. Otherwise, in a step 626, the load 80 remains disconnected. The method ends in step 610.

Here again, as a variant, the steps could be executed in a different order. Some steps could be omitted. The example described does not prevent, in other embodiments, other steps from being carried out jointly and/or sequentially with/to the steps described.

The embodiments and the variants envisaged above may be combined with one another to produce new embodiments.

1. An electrical distribution system for distributing electric currents between an electrical distribution grid and a domestic distribution installation, wherein the system comprises:
a distributor designed to distribute an electric current in the installation, the distributor being configured to have its upstream side connected to an electrical distribution grid and to at least one secondary electrical power supply source, the distributor being configured to have its downstream side connected to a plurality of the electrical loads,
an electronic control device connected to measuring devices associated with the sources and with the loads, these measuring devices allowing determination of the electric current flowing in the installation and in particular of the electric current carried in the electrical distribution grid,
the electronic control device being configured to take the measured current as a basis for managing power supply parameters of at least some of the electrical loads to reduce the electric current consumed by these electrical loads and/or for managing operating parameters of at least some of the secondary electrical power supply sources in order to reduce the electric current delivered by these electrical sources, so as to comply with a first current threshold dictated by a protection element between the electrical installation and the electrical distribution grid and/or a second current threshold corresponding to a current limit dictated by the distributor so as to prevent the current delivered by the electrical sources through the distributor from exceeding the current limit dictated by the distributor.

2. The system according to claim 1, wherein the electronic control device is configured to manage the power supply parameters of at least some of the electrical loads to reduce the electric current consumed by these loads and/or to manage operating parameters of at least some of the secondary electrical power supply sources in order to reduce the electric current delivered by these electrical sources, so as to comply with the first current threshold and the second current threshold.

3. The system according to claim 1, wherein managing power supply parameters of at least some of the electrical loads comprises steps consisting in at least automatically disconnecting or reconnecting said electrical load/s, or modulating the electrical consumption by said electrical load/s.

4. The system according to claim 1, wherein said plurality of electrical loads comprises one or more of the following elements: an electric vehicle or a charging station for an electric vehicle, a water heater, a heat pump, or air-conditioner, or a pump.

5. The system according to claim 1, wherein the system comprises one or more electrical switching devices for selectively disconnecting or reconnecting one or more of said electrical loads, the switching device/s being controlled by the electronic control device.

6. The system according to claim 1, wherein at least one of said electrical loads comprises an integrated regulating device connected to the electronic control device, the integrated regulating device being configured to control the electrical consumption by said electrical load on the basis of information sent by the electronic control device.

7. The system according to claim 6, wherein said electrical load is a charging station for an electric vehicle.

8. The system according to claim 1, wherein each of said electrical loads is connected to the distributor by way of an electrical conductor.

9. The system according to claim 1, wherein at least one secondary electrical power supply source comprises photovoltaic generators.

10. The system according to claim 1, wherein the system comprises at least one electricity storage system that may be a source or a load.

11. The system according to claim 1, wherein an alternative secondary electrical power supply source comprises a generator set.

12. The system according to claim 1, wherein the distributor comprises copper electrical conductors.

13. The system according to claim 1, wherein the protection element comprises an electrical protection unit such as a circuit breaker or a fuse or a power-limited energy meter.

14. The system according to claim 1, wherein the distributor is also configured to have its downstream side connected to additional electrical loads, such as domestic electrical loads, for example lighting.

15. A method for managing an electrical distribution system for distributing electric currents between an electrical distribution grid and an electrical switchboard in a domestic installation, wherein the system comprises a distributor and an electronic control device, the distributor being designed to distribute an electric current in the installation, the distributor being configured to have its upstream side connected to an electrical distribution grid and to at least one secondary electrical power supply source, the distributor being configured to have its downstream side connected to a plurality of electrical loads, wherein the method comprises the electronic control device:
determining, by means of measuring devices associated with the sources and with the loads, the electric currents flowing in the installation, and in particular the electric current carried in the electrical distribution grid,
taking the measured current as a basis for managing power supply parameters of at least some of the electrical loads to reduce the electric current consumed by these electrical loads and/or for managing operating parameters of at least some of the secondary electrical power supply sources in order to reduce the electric current delivered by these electrical sources, so as to comply with a first current threshold dictated by a protection element between the electrical installation and the electrical distribution grid and/or a second current threshold corresponding to a current limit dictated by the distributor so as to prevent the current delivered by the electrical sources through the distributor from exceeding the current limit dictated by the distributor.
